(19) United States
(12) Patent Application Publication
(10) Pub. No.: US 2009/0139749 A1
(43) Pub. Date: Jun. 4, 2009

(54) Method For The Preparation Of A Flexible Transducer Unit, The Flexible Transducer Unit So Prepared And An Array Containing Such Flexible Transducer Units

(76) Inventors: Long-Sheng Fan, San Jose, CA (US); Kuei-Ann Wen, Hsinchu City (TW)

Correspondence Address: VENABLE LLP, P.O. BOX 34385, WASHINGTON, DC, 20043-9998, US

(21) Appl. No.: 12/253,806

(22) Filed: Oct. 17, 2008

Related U.S. Application Data
(60) Provisional application No. 60/980,827, filed on Oct. 18, 2007.

(51) Int. Cl. B44C 1/22; H05K 1/02

(52) U.S. Cl. 174/251; 216/13

(57) ABSTRACT

The present invention relates to a method for the preparation of a flexible transducer unit from a wafer containing a plurality of transducer structures comprising a substrate, a metal-oxide layer, at least one mesh structure in said metal-oxide layer and electric wires including at least one first contact pad in said metal-oxide layer. The method includes the steps of: etch the metal-oxide layer to release said mesh; form a sealing layer on the mesh; form a first flexible material layer on the metal-oxide layer; and remove the substantial thickness of the substrate, sufficient to make the transducer structure flexible. Alternatively the first flexible material layer may be formed before the mesh is released. The method may further include the step of forming a second flexible layer in the back side of the wafer. A novel structure of the flexible transducer unit prepared according to the invented method is also disclosed. An array containing a plurality of the flexible transducer units is also disclosed.

### FIELD OF INVENTION

The present invention discloses a method for the preparation of a flexible transducer unit, especially a method for the preparation of a flexible transducer unit from a wafer wherein a plurality of transducer structure is prepared. The present invention also discloses a novel structure of the flexible transducer unit, prepared according to the above-mentioned method, and an array of such flexible transducer units.

### BACKGROUND OF THE INVENTION

Sensors and actuators applications are typically connected to signal conditioning and driving circuits. It is highly desirable to integrate these circuits with the transducers on the same substrate for reducing parasitic electrical components, increasing signal to noise ratios, managing the addressing of array element in a large array, reducing interconnect and packaging complexity and thus cost, reducing the overall Microsystems sizes etc. Among all the proposed schemes for the transducers and circuits integrations by making the transducers before, during or after the integrated circuits, the approach utilizing the conventional production lines for the integrated circuits and the material layers for the transducer devices, followed by a few post processing steps, is most desirable, since the process may be conducted in the standard IC foundries, without the need of developing customer-design process.

Transducers packaging needs to provide the interfaces of transducers to physical environment or maintain the transducers under certain conditions, such as creating hermetically sealed cavities for inertial sensors or exposed membranes for pressure sensing etc., in additional to providing the conventional device passivation and electrical leads as the regular IC packaging. Thus, Transducers packaging can be more expensive than conventional IC packaging. The wafer-level packaging approach of transducers could reduce the transducers packaging cost by utilizing batch fabrication processes similar to the processing techniques used in microfabrication to provide the interfaces of transducers to physical environment, to maintain the transducers operating conditions, to provide the device passivation and electrical leads. These packaging techniques need to be compatible to the transduction devices and Microsystems.

In many applications such as in medical implants, endoscopic diagnosis tools, or devices to be used on curved or soft surfaces etc. are the packaged intelligent transducers required to have certain flexibility.

### OBJECTIVES OF THE INVENTION

The objective of the present invention is to provide a novel method for the preparation of a flexible transducer unit.

Another objective of the invention is to provide a method for the preparation of flexible transducer units that may be realized in the standard IC fabrication process.

Another objective of this invention is to provide a method for the preparation of flexible transducer units that completes the passivation and the packaging processes.

Another objective of this invention is to provide a novel structure of the flexible transducer unit.

Another objective of this invention is to provide a flexible transducer unit prepared, post processed and packaged according to the IC fabrication process.

Another objective of this invention is to provide an array of flexible transducer unit prepared according to the invented method.

Another objective of this invention is to provide an array of flexible transducer unit prepared, post processed and packaged according to the IC fabrication process

### SUMMARY OF THE INVENTION

The present invention provides a method for the post processing of a transducer structure. The Transducer structure generally comprises a substrate, a metal-oxide layer, at least one mesh structure in said metal-oxide layer and electric wires including at least one first contact pad in said metal-oxide layer. In most applications of the present invention a plurality of the transducers is prepared in one substrate, which may be a silicon substrate, more particularly a SOI substrate.

In one aspect of this invention, the post processing method of this invention comprises the steps of:
etch the metal-oxide layer to release said mesh;
form a sealing layer on the mesh;
form a first flexible material layer on the metal-oxide layer; and
remove the substantial thickness of the substrate, sufficient to make the transducer structure flexible.

In the embodiments of the present invention, the substrate is removed by etching, particularly by a lapping process. Also in the embodiments, the substrate is in substtance completely removed.

In another aspect of this invention, the post processing method comprises of:

form a first flexible material layer on the metal-oxide layer of the transducer structure;

expose the metal-oxide layer in areas where the mesh is provided;

etch the metal-oxide layer to release the mesh;

form a sealing layer on the mesh;

remove the substantial thickness of the substrate, to make the transducer structure flexible.

Similarly, the substrate may be removed by etching, particularly by a lapping process. Also, the substrate may be in substance completely removed.

A second flexible material layer may be formed on the exposed metal-oxide layer after removing the substrate. After the first flexible material layer is formed, exposing the contact pad of the electric wires may be necessary. Similarly, after the second flexible material layer is formed, exposing the second contact pad of the electric wires may be necessary.

The mesh in the present invention is the main structure of the transducer and may be a metal mesh, particularly a metal mesh prepared according to the CMOS process. The transducer structure may further comprise a metal-oxide stack prepared in the metal-oxide layer. When releasing the mesh, the metal-oxide stack may also be released. The metal-oxide stack is prepared in a way that the metal layers in the metal-oxide layer to be removed are interconnected by metal vias in the metal-oxide layer and edges of the metal layers are exposed after the mesh releasing step.

To release the mesh, and the metal-oxide stack as well, an isotropic silicon oxides etching of the metal-oxide layer at the area where the mesh is provided, may be used. The isotropic silicon oxides etching of the metal-oxide layer stops at an underneath polysilicon layer prepared in the metal-oxide layer or at the surface of the substrate. The etching process may further comprise subjecting the transducer structure to the combination of an anisotropic etching and an isotropic silicon etching, to produce an undercut in the substrate.

The resealing of the mesh may be conducted in vapor phase to produce a PECVD film or a polymer film, of such as Teflon or Parylene. The first and second flexible layers may be the same in their materials and their structure. The polymer is desirable in forming the first and second flexible layer. Suited materials include polyimide, Teflon and Parylene.

The transducer structure may be bonded to a carrier wafer after having formed the first flexible layer on the metal-oxide layer. The carrier wafer is removed after the substrate is substantially removed or after the a second flexible layer is formed.

To substantially remove the substrate, a course etching and a fine etching may be used. In the course etching, the substrate is subjected to a lapping process, leaving a much thinner layer, typically in the range of 50 um, whereby the electronic devices are intact. Thereafter, the remaining thin layer silicon substrate is further removed by a wet etching, RIE/plasma etching or a gas phase etching. After these steps, the transducer is ready for separation. The plurality of the transducer structures prepared in the first flexible layer, and the second flexible layer if applicable, is separated to dice. In another embodiment of this invention, the metal-oxide layer at predetermined separation lanes is completely removed in the preparation of the transducer structure. In forming the first flexible layer, the flexible material fills the space of the removed metal-oxide layer. Thereby, when cutting the wafer, no metal-oxide layer will be exposed after the dice are separated.

According to the present invention, the flexible transducer unit prepared according to the invented method will comprise: a first flexible layer, a metal-oxide layer in connection with a first surface of said first flexible layer, electronic wires in connection with a first contact pad, both buried in said metal-oxide layer, a mesh suspended in said metal-oxide layer and a sealing layer covering at least said mesh. The flexible transducer unit may comprise a residual substrate in connection with a second side of said metal-oxide layer, if the substrate is not completely removed. The transducer unit may further comprise a second flexible layer in connection with the residual substrate or the second side of the metal-oxide layer.

In the transducer structure a metal-oxide stack suspended in said oxide-metal layer may further be provided. The metal layers in said metal-oxide stack are interconnected by metal vias in the metal-oxide layer and edges of the metal layers are exposed. The metal-oxide stack comprises metal layers in a number selected from one to the total number of metal layers in said metal-oxide layer. The transducer structure may also include a polysilicon layer extending parallel to and at a distance with the mesh. The polysilicon may function as an electrode. If necessary, the first contact pad is exposed from the first flexible layer. A second contact pad may also be provided. Similarly, the second contact pad may be exposed from the second flexible layer. The sealing layer may also cover the first flexible layer.

While the flexible transducer units are prepared in a wafer, an array of transducer units with the above-mentioned features may be prepared in a batch. The transducer units in the wafer may be separated by the first flexible layer, if the metal-oxide layer among the transducer units is completed removed and the space thereof is later filled by the first flexible layer.

These and other objectives and advantages may be clearly understood from the detailed description by referring to the following drawings.

### BRIEF DESCRIPTION OF THE DRAWINGS

FIGS. 1(a)-1(c) illustrate the several steps in the method for the preparation of a flexible transducer unit according to the first embodiment of the present invention.

FIGS. 2(a)-2(c) show the several steps in the method for the preparation of a flexible transducer unit according to the second embodiment of the present invention.

FIGS. 3(a)-3(c) show the several steps in the method for the preparation of a flexible transducer unit according to the third embodiment of the present invention.

FIGS. 4(a)-3(c) show the several steps in the method for the preparation of a flexible transducer unit according to the fourth embodiment of the present invention.

FIG. 5 shows the cross-sectional view of a transducer structure finished after the process according to the fifth embodiment of this invention.

FIG. 6 shows the cross-sectional view of a plurality of transducer structures after the method for the preparation of a flexible transducer unit according to the sixth embodiment of the present invention.

### DETAILED DESCRIPTION OF THE INVENTION

The present invention discloses the integrations and the packaging of electronic circuits and micro transducers, making the final integrated devices flexible and/or biocompatible. The present invention shows that the intermixing of the integrated circuit fabrication process, the transducer fabrication process and the wafer-level packaging process may be completed at one time in the standard IC fabrication process. Micro transducers can be formed and packaged in the circuit integration process. It is thus not necessary to fabricate the electronic circuits, the micro transducers and packaging the transducer units separately or sequentially in separated fabrication equipments, as necessary in the conventional art. The invented method can be used to produce implement devices such as the acoustic imaging devices for diagnosis and monitoring the human body, the partially vacuum-sealed oscillators, the micro accelerometers and the gyroscopes, pressure sensors, the flow rate & acoustic sensors etc. It can also be used on to produce devices with curved or soft surface or for implantable/wearable applications.

The invented method for the preparation of a flexible transducer unit generally relates to the post processing of a transducer microstructure and the process may be understood as follows: After the microfabrication process of integrated circuits on an SOI wafer, resulted at the top silicon layer thickness ranging from a fraction of a micrometer to a few micrometers, with desired electronic components and transducers structure contained in the metal-oxide layer, the transducers are subjected to the invented post processing steps to complete their preparations. The present invention prepares the flexible transducer unit from a wafer that contains a plurality of transducer structure, which includes: a substrate, a metal-oxide layer, at least one mesh structure in the metal-oxide layer and electric wires including at least one contact pad in the metal-oxide layer. The method for the preparation of a flexible transducer unit of this includes the steps of: At first, the transducer structure and the cavity ceiling mesh are released by such as the HF-based chemical etching. The transducer structure and the cavity ceiling mesh are then re-sealed by a vapor-phase deposited material or materials to form the cavity ceiling. To make the whole device flexible, a polymer layer (such as Polyimide, Parylene or Teflon etc.) is deposited on the front side of the wafer, leaving the transducers area exposed. The wafer is bonded to a carrier wafer. In an alternative embodiment, the front-side polymer can be deposited before the transducer structure and the mesh are released. Thereafter, the backside silicon substrate is removed by a lapping process to a relatively thin thickness, typically in the 50 um range, keeping the electronic devices intact. The remaining thin silicon layer is further removed by a wet etching, RIE/plasma etching or a gas phase etching. The oxide layer buried in the thin silicon layer is used as the etch stop. The backside is then covered by another polymer layer which can be the same or different in material as that of the front side. A symmetrical geometry and compatible material in the two polymer layers are desirable, since they will minimize the stress that the active parts of the electronic devices and the transducers would experience. Finally, the now flexible wafer is de-bonded before or after it is cut into individual dice.

The following is detailed descriptions of the several embodiments of the present invention. It shall be noted that the description to the preferred embodiments is for illustration purpose, without the intention to limit the scope of this invention.

### EMBODIMENT I

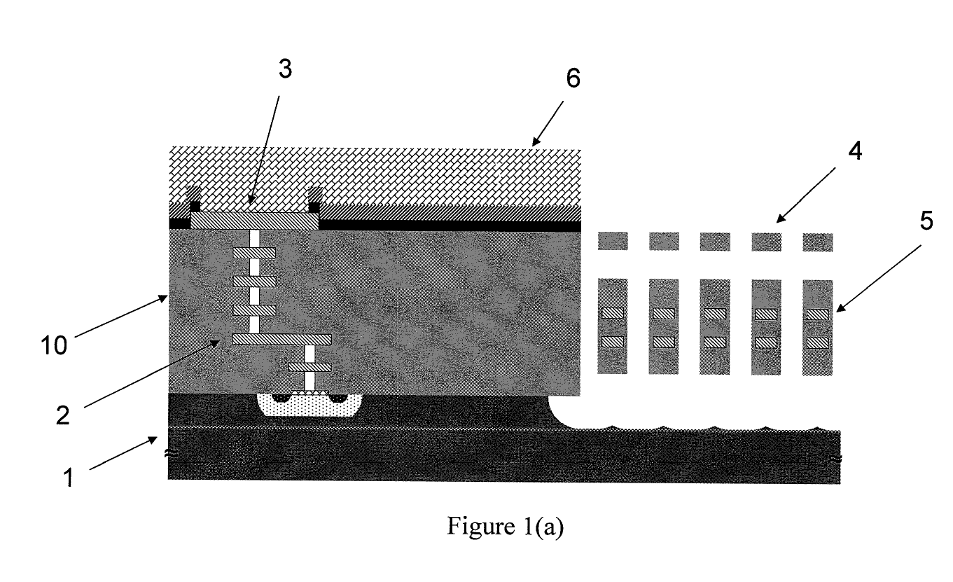

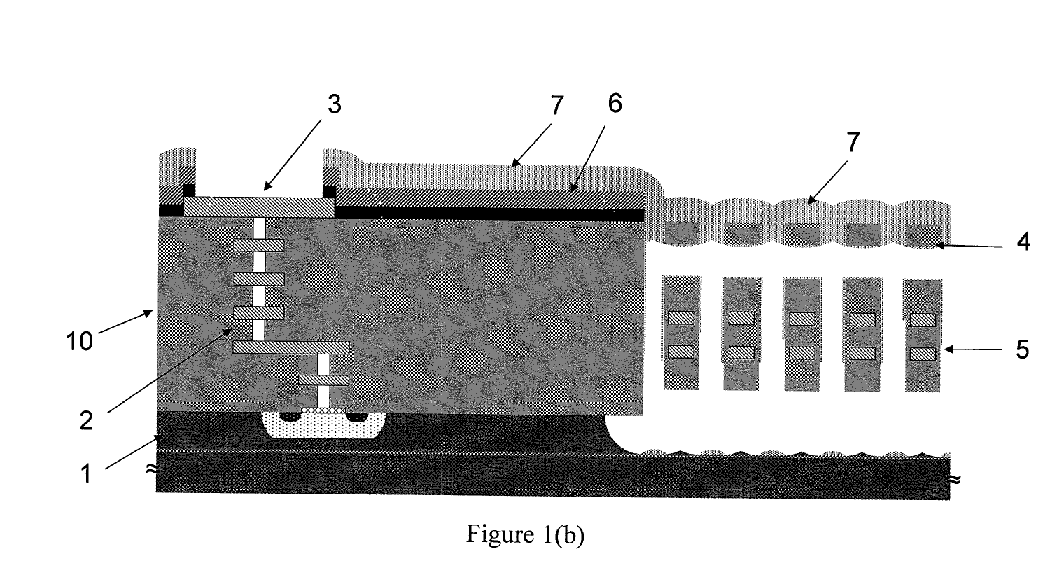

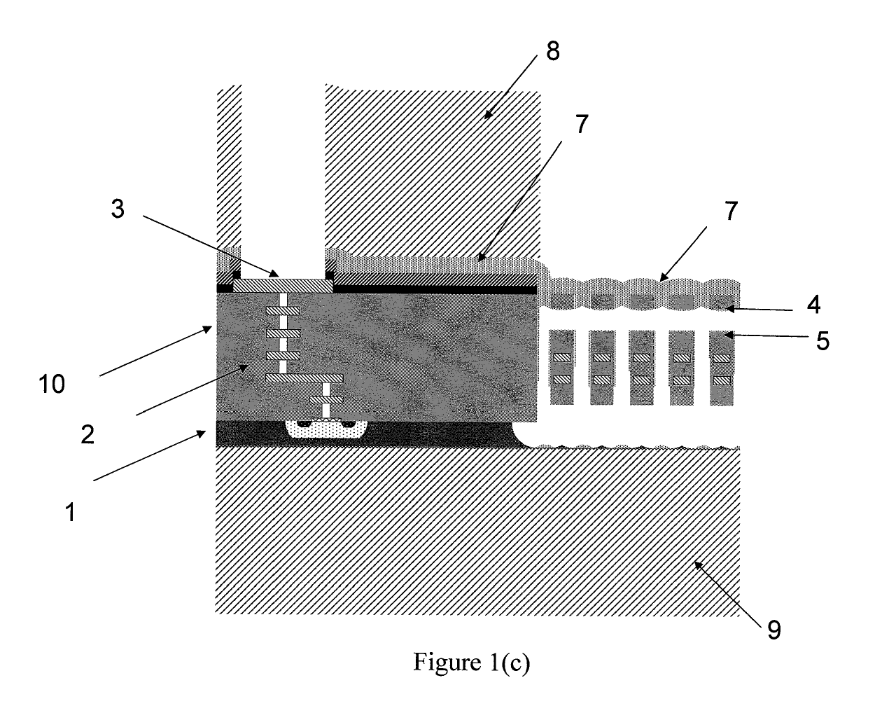

FIGS. 1(a)-1(c) illustrate the several steps in the method for the preparation of a flexible transducer unit according to the first embodiment of the present invention.

As shown in these figures, in this embodiment a wafer containing a structure including a transducer is first prepared. FIG. 1(a) shows the cross sectional view of the transducer structure. As shown, the transducer structure includes: A silicon substrate 1, a metal-oxide layer 10, metal wires 2 connected to a contact pad 3, both buried in the metal-oxide layer 10, a metal mesh 4 and a metal-oxide stack 5, both exposed from the metal-oxide layer 10, and a protection layer 6 covering the upper surface of the metal-oxide layer 10, i.e., the “front side.”

The structure shown in FIG. 1(a) is fabricated by a conventional IC process on an SOI wafer, in particular the CMOS process, followed by a photolithography step to cover the wafer surface with the protection layer 6 except for those areas where the mesh 4 is provided, an anisotropic silicon oxides etching step to expose the metal mesh 4 and a combination of the anisotropic and the isotropic silicon etching steps to release the metal-oxide stack 5. Another wet metal etch process is then applied to remove at least one metal interlayer (not shown). The metal-oxide stack 5 is designed in such a way that metal layers to be removed are interconnected by metal vias and the edges of these metal layers are exposed after the previous anisotropic silicon oxides etching step. Thus, the metal-oxide stack 5 is separated into groups, with the upper most group functioning as the ceiling mesh 4. In this FIG. 1(a) two groups of the metal-oxide sacks are shown. The first group is the metal-oxide stack labeled as 5 and the second is the mesh labeled as 4.

The design of the meal-oxide stack 5 (and the mesh 4) provides the possibility of producing elastic layers suspended in the wafer structure, either exposed or sealed, with various selections in the number of metal layers contained in the elastic layers, thickness and strength of the elastic layers, height of the space between elastic layers and between an elastic layer and the sealing or the substrate. These factors may be controlled by the width of each metal layer or oxide layer and the etching rates.

The wafer is processed to reseal the ceiling mesh 4. The reseal process is conducted in vapor phase to produce a PECVD film or a sealing layer 7, e.g., a polymer film such as Teflon, Parylene etc., on the ceiling mesh 4, as well as on the protection later 6 and the electrode pad 3. Optional photolithography and RIE steps are used afterward for pad opening, if electrical accessing to the devices is needed. This step is not essential for, such as, passive RFID devices. The cross section of the structure so produced is shown in FIG. 1(b).

To make the whole device flexible, a polymer layer 8, such as Polyimide, Parylene or Teflon etc., is deposited on the front side of the wafer, on top of the sealing layer 7. Thereafter, the structure is treated using the conventional art to have the transducer areas and/or the pad areas exposed. This is done by, for example, an optional photolithography and an RIE steps to etch off the sealing layer 7 and the front side polymer layer 8 at the areas where the pads and the transducer locate. The structure is then bonded to a carrier wafer (not shown). The resulted structure is shown in FIG. 1(c).

In the next step, the backside silicon substrate 1 is removed by a lapping process, leaving a much thinner layer, typically in the range of 50 um, whereby the electronic devices are intact. Thereafter, the remaining thin layer silicon substrate 1 is further removed by a wet etching, RIE/plasma etching or a gas phase etching. The buried oxide layer in the metal-oxide layer 10 is used as the etch stop. The backside is then covered again by another polymer layer 9. The backside polymer layer 9 may be the same or different in material as that of the front side. The cross sectional view of the structure so produced is shown in FIG. 1(c). Finally, the now flexible wafer is de-bonded from the carrier wafer, before or after it is cut into individual dice.

### EMBODIMENT II

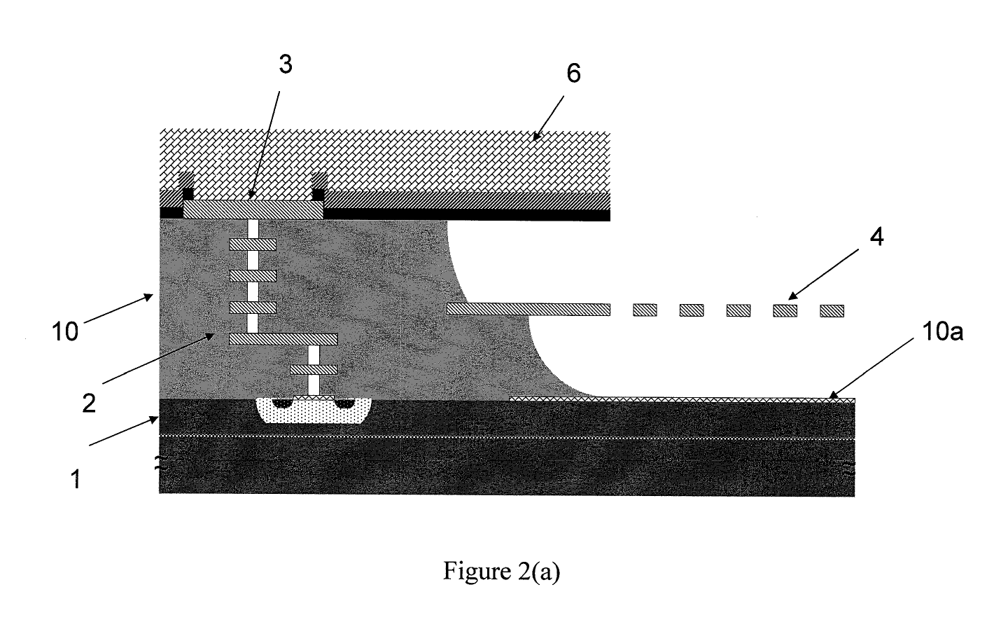

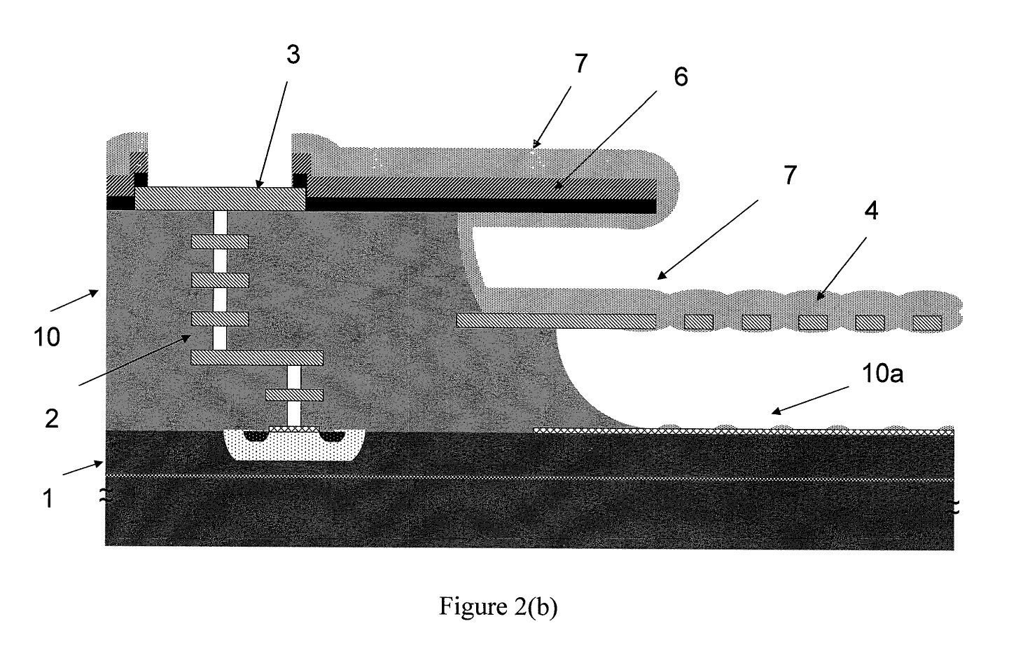

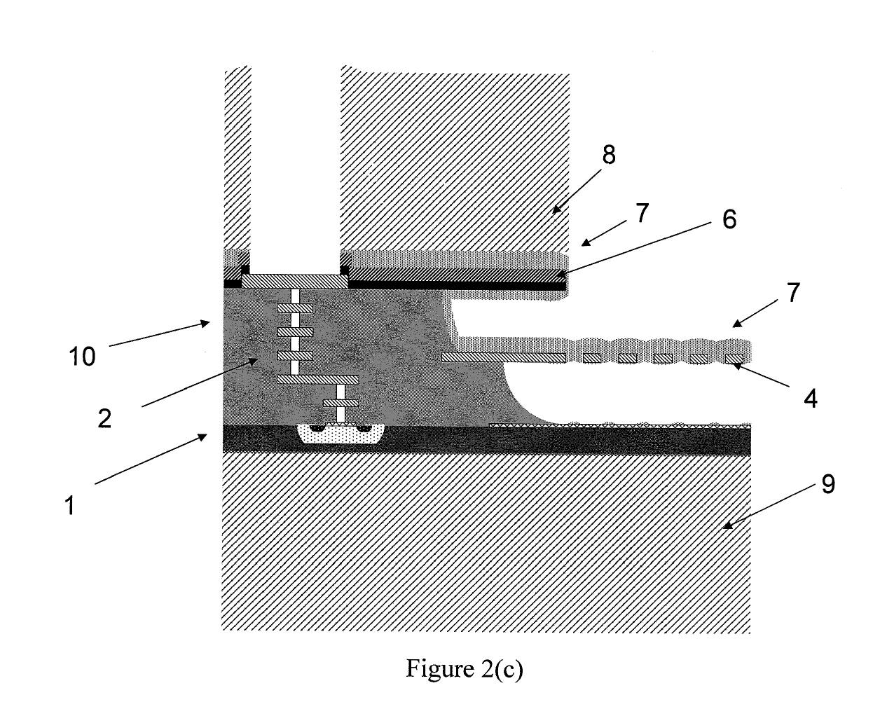

FIGS. 2(a)-2(c) show the several steps in the method for the preparation of a flexible transducer unit according to the second embodiment of the present invention. In these drawings, those components that are the same as in FIGS. 1(a)-1(c) are labeled with the same figures. In them, FIG. 2(a) shows the cross-sectional view of a transducer structure including a silicon substrate 1, a metal-oxide layer 10, metal wires 2 connected to an electrode 3, both buried in the metal-oxide layer 10, a metal mesh 4 exposed from the metal-oxide layer 10, and a protection layer 6 covering the front side of the wafer.

The structure is fabricated by the conventional IC process to produce the circuits 2 and the metal mesh 4 on an SOI wafer. A photolithography step covers the wafer surface, except for the areas where the transducer is provided. An isotropic silicon oxides etching releases the mesh 4 and stops at an underneath polysilicon layer 10a or the surface at surface of the silicon substrate 1. Some other structure layers may also be released. When the polysilicon layer 10a is provided, the resulted transducer structure provides the possibility of using the polysilicon layer as one eletrode of the transducer.

The wafer is further processed to seal the ceiling mesh 4. The reseal process is conducted in vapor phase to produce a PECVD film or a polymer film as the sealing layer 7. The polymer used here may be Teflon, Parylene etc. Optional photolithography and RIE steps are used thereafter for pad opening, if electrical accessing to the devices is needed in the application of the transducer. This step is not necessary if the structure will be used as a passive RFID device. The cross sectional view of the structure obtained is shown FIG. 2(b).

To make the whole device flexible, a polymer layer 8, such as Polyimide, Parylene or Teflon etc., is deposited on the front side of the wafer. Thereafter, the structure is treated using the conventional art to have the transducer areas and/or the pad areas exposed. This is done by, for example, an optional photolithography and an RIE steps to etch off the sealing layer 7 and the front side polymer layer 8 at the areas where the pads and the transducer locate. The structure is then bonded to a carrier wafer (not shown). The resulted structure is shown in FIG. 2(c).

In the next step, the backside silicon substrate is removed by a lapping process, leaving a much thinner layer, typically in the range of 50 um, whereby the electronic devices are intact. Thereafter, the remaining thin layer silicon substrate 1 is further removed by a wet etching, RIE/plasma etching or a gas phase etching. The buried oxide layer in the metal-oxide layer 10 is used as the etch stop. The backside is then covered again by another polymer layer 9. The backside polymer layer 9 may be the same or different in material as that of the front side. The cross sectional view of the structure so produced is shown in FIG. 2(c). Finally, the now flexible wafer is de-bonded from the carrier wafer, before or after it is cut into individual dice.

### EMBODIMENT III

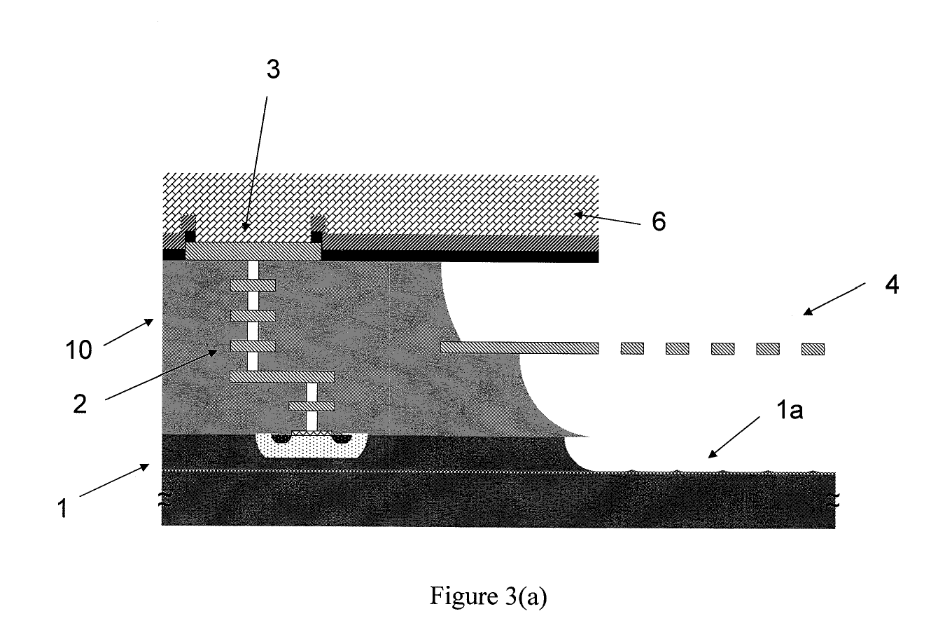

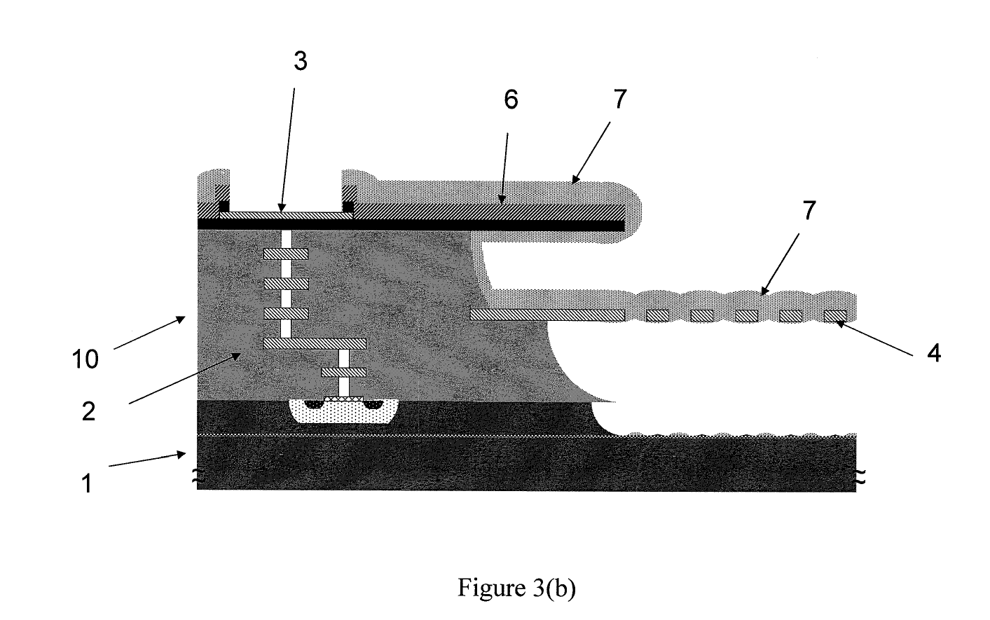

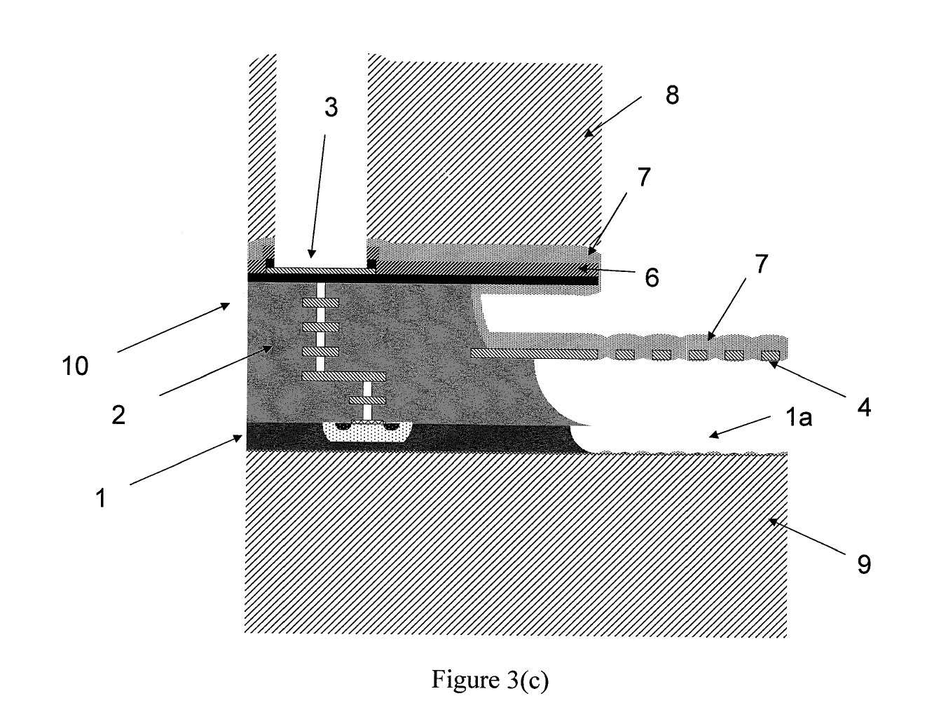

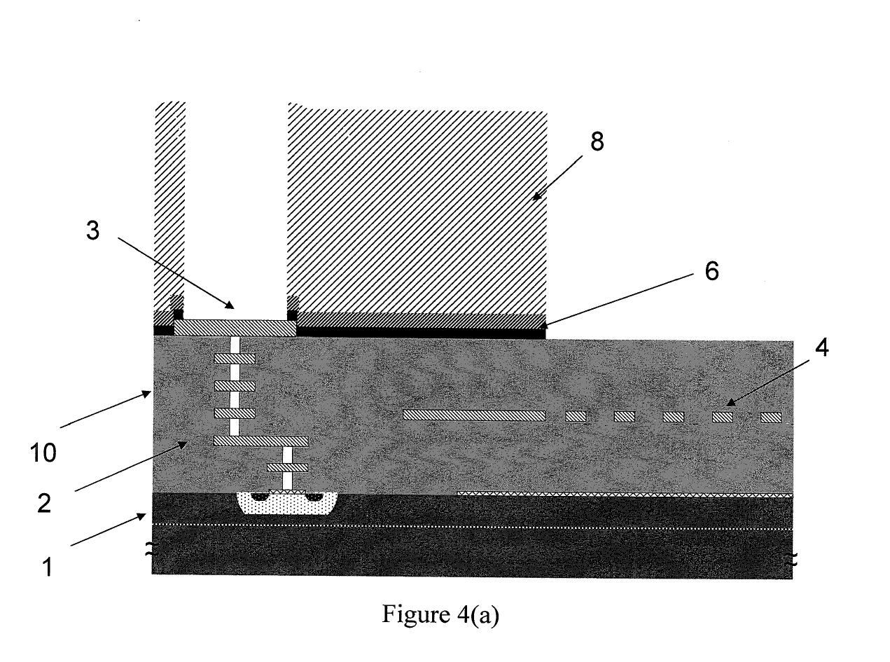

FIGS. 3(a)-3(c) show the several steps in the method for the preparation of a flexible transducer unit according to the third embodiment of the present invention. In these drawings, those components that are the same as in FIGS. 2(a)-2(c) are labeled with the same figures. In them, FIG. 3(a) shows the cross-sectional view of a transducer structure including a silicon substrate 1, a metal-oxide layer 10, metal wires 2 connected to an electrode 3, both buried in the metal-oxide layer 10, a metal mesh 4 exposed from the metal-oxide layer 10, and a protection layer 6 covering the front side of the wafer.

The structure is fabricated by the conventional IC process to form the circuits 2 and the metal mesh 4 on an SOI wafer. A photolithography step covers the wafer surface, except for the areas where the transducer is provided. An isotropic silicon oxides etching releases the mesh 4 and stops at the surface of the underneath silicon substrate 1 or the silicon substrate surface 1. Some other structure layers may also be released. The transducer structure is subjected further to a combination of the anisotropic and the isotropic silicon etching steps to create an undercut 1a in the silicon substrate 1. With the undercut 1a, the height of the chamber at the backside of the mesh 4 is not limited to the height of the metal-oxide layer 10.

The wafer is further processed to seal the ceiling mesh 4. The reseal process is conducted in vapor phase to produce a PECVD film or a polymer film as the sealing layer 7 to seal the mesh 4. The polymer used here may be Teflon, Parylene etc. Optional photolithography and RIE steps are used thereafter for pad opening if electrical accessing to the devices is needed in the application of the transducer. This step is not necessary if the structure will be used as a passive RFID device. The cross sectional view of the structure obtained is shown FIG. 3(b).

To make the whole device flexible, a polymer layer 8, such as Polyimide, Parylene or Teflon etc., is deposited on the front side of the wafer. Thereafter, the structure is treated using the conventional art to have the transducer areas and/or the pad areas exposed. This is done by, for example, an optional photolithography and an RIE steps to etch off the sealing layer 7 and the front side polymer layer 8 at the areas where the pads and the transducer locate. The structure is then bonded to a carrier wafer (not shown). The resulted structure is shown in FIG. 2(c).

In the next step, the backside silicon substrate 1 is removed by a lapping process, leaving a much thinner layer, typically in the range of 50 um, whereby the electronic devices are intact. Thereafter, the remaining thin layer silicon substrate 1 is further removed by a wet etching, RIE/plasma etching or a gas phase etching step. The buried oxide layer in the metal-oxide layer 10 is used as the etch stop. The backside of the wafer is then covered again by another polymer layer 9. The backside polymer layer 9 may be the same or different in material as that of the front side. The cross section of the structure so produced is shown in FIG. 3(c). Finally, the now flexible wafer is de-bonded from the carrier wafer, before or after it is cut into individual dice.

### EMBODIMENT IV

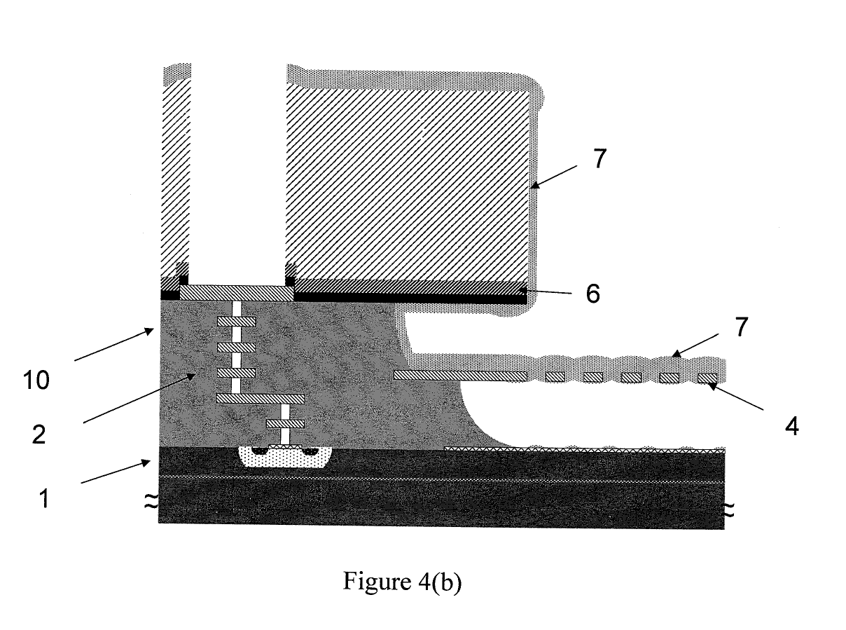

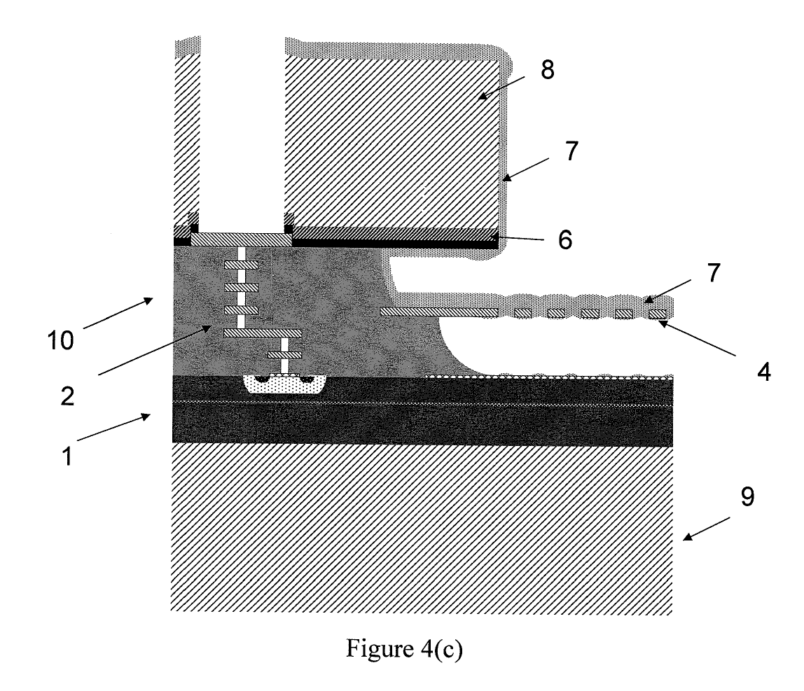

FIGS. 4(a)-4(c) show the several steps in the method for the preparation of a flexible transducer unit according to the fourth embodiment of the present invention. In these drawings, those components that are the same as in FIGS. 2(a)-1(c) are labeled with the same figures. In them, FIG. 4(a) shows the cross-sectional view of a transducer structure including a silicon substrate 1, a metal-oxide layer 10, metal wires 2 connected to an electrode 3, both buried in the metal-oxide layer 10, a metal mesh 4 exposed from the metal-oxide layer 10, and a protection layer 6 covering the front side of the wafer. The transducer structure is fabricated according to the same or similar approaches as shown in Embodiment II.

In this embodiment, the steps are similar to those in Embodiment II, except that the front-side polymer layer 8 is applied to the transducer structure before the metal mesh 4 is released and resealed.

In FIG. 4(a) it is shown that the front side polymer layer 8 is applied to the front-side of the wafer before the metal mesh 4 is released. The metal pad 3 and the transducer (mesh) areas are exposed after necessary conventional process. In FIG. 4(b) the metal mesh 4 is released using the same art as in Embodiment II. A sealing layer 7 is then applied to cover the metal mesh 4 and the front side polymer layer 8. In FIG. 4(c) the back-side silicon substrate 1 is etched to remove the unnecessary thickness by the same arts as described in Embodiment II. Finally, another polymer layer 9 is applied to the back-side of the wafer.

### EMBODIMENT V

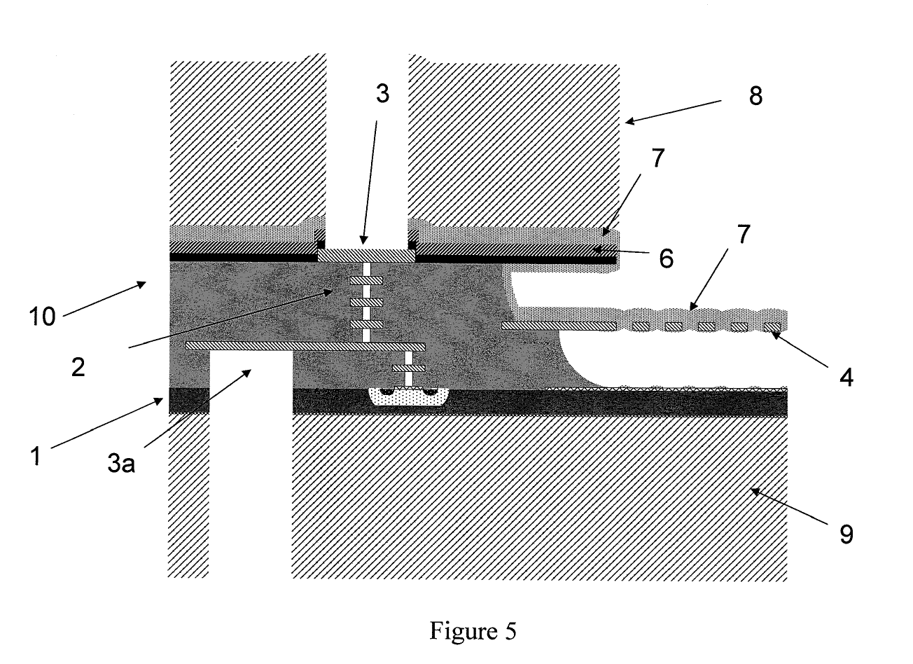

FIG. 5 shows the cross-sectional view of a transducer structure finished after the process according to the fifth embodiment of this invention. In this figure, the components that are the same as in FIGS. 2(a)-2(c) are labeled with the same numbers. As shown in this figure, the transducer structure prepared according to this embodiment includes a second contact pad 3a to be exposed in the back-side of the wafer. Therefore, in this embodiment, the process are the same as those in the Embodiment II, except that the second pad 3a is prepared in the preparation of the transducer structure and that the second pad 3a is exposed from the metal-oxide layer 10.

This may be done by the steps of, after the metal mesh 4 is released and resealed, that the back-side silicon substrate 1 is removed, that the buried silicon-oxide layer is removed, that the following thin silicon layer and that the silicon-oxide layer are removed, whereby one of the metal layers in which the contact pads 3a is predefined, is exposed from the back side of the wafer. The back-side polymer 9 is then deposed, followed by the pad opening steps to expose the pad 3a, before dice are separated.

### EMBODIMENT VI

### Preparations for Die Separation

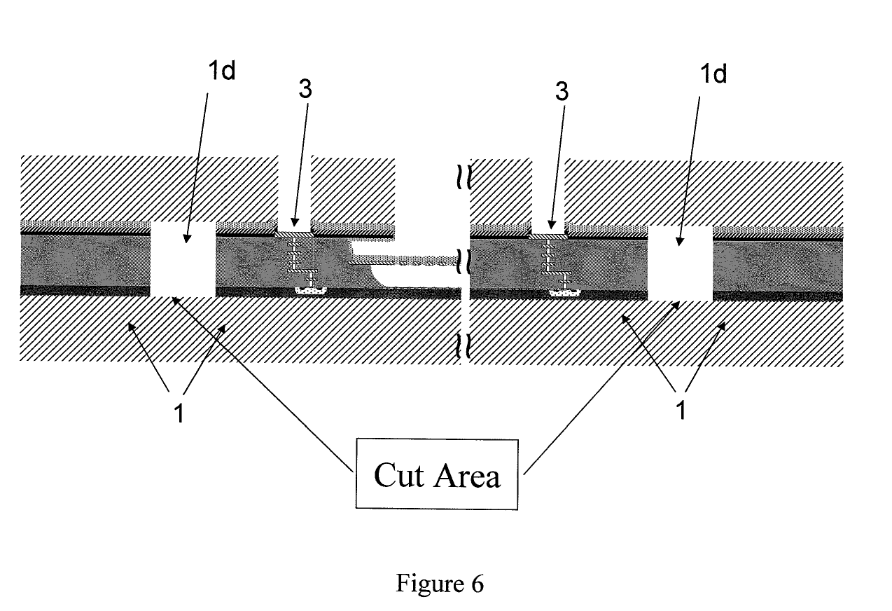

FIG. 6 shows the cross-sectional view of a plurality of transducer structures after the process according to the sixth embodiment of the present invention. In this figure, the components that are the same as in FIGS. 2(a)-2(c) are labeled with the same numbers.

In this embodiment, the process relates to the pre-separation of the transducer units embedded in the polymer sandwich. This is done by completely removing the oxide layers down to the substrate 1 at the separation lane areas 1d of the front side in the preparation of the transducer structures. The oxide layers at the separation lanes are totally removed using, for example, the anisotropic etch processes of the silicon-oxide layer and the thin silicon layer during the preparation of the transducer structure, if the approach of Embodiment I is used. In the case of the Embodiment III, the removal of the separation lanes is realized by the combination of the isotropic oxide removal and the anisotropic silicon removal. The mesh release and reseal processes and the front side polymer layer deposition process are the same as those in Embodiments I-III. Thereafter, the backside substrate 1 is removed and the buried silicon-oxide layer is also removed, in the same manners as those in Embodiment I-Ill. The backside polymer deposition and the pad opening steps followed, thereby a wafer containing a plurality of pre-separated transducer units is prepared.

The wafer is then subjected to separation by cutting at the separation lanes Id. Since only the polymer layer 8 remains in the separation lanes 1d, in the die separation step the silicon and oxide crack propagation will be greatly minimized or eliminated.

As the present invention has been shown and described with reference to preferred embodiments thereof, those skilled in the art will recognize that the above and other changes may be made therein without departing form the spirit and scope of the invention.

For example, in the post process of the transducer structure, the backside polymer passivation may not be needed in some special situations, such as when the finished transducer will be used in a well-controlled and low-pollution operation environment or when other following-on passivation steps are performed after the flexible transducer die is attached in its desired applications.

Furthermore, when the transducers are hermetically sealed in cavities and are integrated with or without electronic circuits in the wafer-level packaging processes, thinning down the substrate 1 to the extend that the substrate 1 is flexible may not be necessary.

What is claimed is:

1. A method for the preparation of a flexible transducer unit from a transducer structure comprising a substrate, a metal-oxide layer, at least one mesh structure in said metal-oxide layer and electric wires including at least one first contact pad in said metal-oxide layer, comprising the steps of:
etch said metal-oxide layer to release said mesh;
form a sealing layer on said mesh;
form a first flexible material layer on said metal-oxide layer; and
remove the substantial thickness of said substrate, sufficient to make the transducer structure flexible.

2. The method according to claim 1, wherein said substrate is removed by etching.

3. The method according to claim 1, wherein said substrate is removed by a lapping process.

4. The method according to claim 1, wherein said substrate is substantially completely removed.

5. The method according to claim 1, further comprising the step of applying a second flexible material layer on the backside of said substrate

6. The method according to claim 4, further comprising the step of applying a second flexible material layer on the exposed metal-oxide layer after removing said substrate.

7. The method according to claim 1, further comprising the step of exposing said contact pad of said electric wires after said step of applying said first flexible material layer.

8. The method according to claim 5, further comprising the step of exposing a second contact pad of said electric wires after said step of applying said second flexible material layer.

9. The method according to claim 6, further comprising the step of exposing a second contact pad of said electric wires after said step of applying said second flexible material layer.

10. The method according to claim 1, further comprising the step of separating said transducer structure to form a die.

11. The method according to claim 1, wherein said substrate comprises silicon.

12. The method according to claim 1, wherein said mesh is a metal mesh.

13. The method according to claim 12, wherein said mesh is a metal mesh prepared according to the CMOS process.

14. The method according to claim 1, wherein said substrate further comprises a metal-oxide stack and said step of releasing said mesh further comprises the step of releasing said metal-oxide stack.

15. The method according to claim 14, wherein said metal-oxide stack is prepared in a way that metal layers in said metal-oxide layer to be removed are interconnected by metal vias in said metal-oxide layer and edges of said metal layers are exposed after said mesh releasing step.

16. The method according to claim 1, wherein said step of releasing said mesh comprising the steps of isotropic silicon oxides etching said metal-oxide layer at an area where said mesh is provided.

17. The method according to claim 16, wherein said isotropic silicon oxides etching of said releases stops at an underneath polysilicon lay prepared in said metal-oxide layer.

18. The method according to claim 16, wherein said isotropic silicon oxides etching of said releases stops at the surface of said silicon substrate.

19. The method according to claim 16, wherein said step of releasing said mesh further comprises the step of subjecting said transducer structure to a combination of an anisotropic etching and an isotropic silicon etching, to produce an undercut in said substrate.

20. The method according to claim 1, wherein said step of resealing said mesh is conducted in vapor phase to produce a PECVD film.

21. The method according to claim 1, wherein said step of resealing said mesh is conducted in vapor phase to produce a polymer film.

22. The method according to claim 21, wherein said polymer film is one selected from the group consisted of Teflon and Parylene.

23. The method according to claim 1, wherein said first flexible material comprises a polymer layer.

24. The method according to claim 23, wherein said polymer layer is one selected from the group consisted of Polyimide, Parylene and Teflon.

25. The method according to claim 1, wherein said second flexible material comprises a polymer layer.

26. The method according to claim 25, wherein said polymer layer is one selected from the group consisted of Polyimide, Parylene and Teflon.

27. The method according to claim 1, further comprising the step of bonding said transducer structure to a carrier wafer after forming said first flexible layer on said metal-oxide layer.

28. The method according to claim 5, further comprising the steps of bonding said transducer structure to a carrier wafer after forming said first flexible layer on said metal-oxide layer and removing said carrier wafer after forming said second flexible layer on said exposed metal-oxide layer.

29. The method according to claim 6, further comprising the steps of bonding said transducer structure to a carrier wafer after forming said first flexible layer on said metal-oxide layer and removing said carrier wafer after forming said second flexible layer on said exposed metal-oxide layer.

30. The method according to claim 1, wherein removal of said substrate comprising a course etching of said substrate and a fine etching of said substrate, wherein said fine etching comprising the step of removing remaining of said substrate after said course etching by an etching selected from the group consisted of wet etching, RIE/plasma etching and gas phase etching.

31. The method according to claim 1, wherein said metal-oxide layer at predetermined separation lanes are completely removed in the preparation of the transducer structure.

32. A method for the preparation of a flexible transducer unit from a transducer structure comprising a substrate, a metal-oxide layer, at least one mesh structure in said metal-oxide layer and electric wires including at least one first contact pad in said metal-oxide layer, comprising the steps of:
form a first flexible material layer on said metal-oxide layer;
expose said metal-oxide layer in areas where said mesh is provided;
etch said metal-oxide layer to release said mesh;
form a sealing layer on said mesh;
remove the substantial thickness of said substrate, sufficient to make the transducer structure flexible.

33. The method according to claim 32, wherein said substrate is substantially completely removed.

34. The method according to claim 33, further comprising the step of applying a second flexible material layer on the exposed metal-oxide layer after removing said substrate.

35. The method according to claim 32, further comprising the step of applying a second flexible material layer on the backside of said substrate.

36. The method according to claim 32, further comprising the step of exposing said contact pad of said electric wires after said step of applying said first flexible material layer.

37. The method according to claim 36, further comprising the step of exposing a second contact pad of said electric wires after said step of applying said second flexible material layer.

38. The method according to claim 32, further comprising the step of separating said transducer structure to form a die.

39. The method according to claim 32, wherein said mesh is a metal mesh prepared according to the CMOS process.

40. The method according to claim 32, wherein said substrate further comprises a metal-oxide stack and said step of releasing said mesh further comprises the step of releasing said metal-oxide stack.

41. The method according to claim 40, wherein said metal-oxide stack is prepared in a way that metal layers in said metal-oxide layer to be removed are interconnected by metal vias in said metal-oxide layer and edges of said metal layers are exposed after said mesh releasing step.

42. The method according to claim 32, wherein said step of releasing said mesh comprising the steps of isotropic silicon oxides etching said metal-oxide layer at an area where said mesh is provided.

43. The method according to claim 42, wherein said isotropic silicon oxides etching of said releases stops at an underneath polysilicon lay prepared in said metal-oxide layer.

44. The method according to claim 42, wherein said isotropic silicon oxides etching of said releases stops at the surface of said silicon substrate.

45. The method according to claim 42, wherein said step of releasing said mesh further comprises the step of subjecting said transducer structure to a combination of an anisotropic etching and an isotropic silicon etching, to produce an undercut in said substrate.

46. The method according to claim 32, wherein said step of resealing said mesh is conducted in vapor phase to produce a PECVD film.

47. The method according to claim 32, wherein said step of resealing said mesh is conducted in vapor phase to produce a polymer film.

48. The method according to claim 47, wherein said polymer film is one selected from the group consisted of Teflon and Parylene.

49. The method according to claim 32, wherein said first flexible material comprises a polymer layer.

50. The method according to claim 49, wherein said polymer layer is one selected from the group consisted of Polyimide, Parylene and Teflon.

51. The method according to claim 32, further comprising the step of bonding said transducer structure to a carrier wafer after forming said first flexible layer on said metal-oxide layer.

52. The method according to claim 34, further comprising the steps of bonding said transducer structure to a carrier wafer after forming said first flexible layer on said metal-oxide layer and removing said carrier wafer after forming said second flexible layer on said exposed metal-oxide layer.

53. The method according to claim 35, further comprising the steps of bonding said transducer structure to a carrier wafer after forming said first flexible layer on said metal-oxide layer and removing said carrier wafer after forming said second flexible layer on said exposed metal-oxide layer.

54. The method according to claim 32, wherein removal of said substrate comprising a course etching of said substrate and a fine etching of said substrate, wherein said fine etching comprising the step of removing remaining of said substrate after said course etching by an etching selected from the group consisted of wet etching, RIE/plasma etching and gas phase etching.

55. The method according to claim 32, wherein said metal-oxide layer at predetermined separation lanes are completely removed in the preparation of the transducer structure.

56. The method according to claim 32, wherein said second flexible material comprises a polymer layer.

57. The method according to claim 56, wherein said polymer layer is one selected from the group consisted of Polyimide, Parylene and Teflon.

58. A transducer structure, comprising a first flexible layer, a metal-oxide layer in connection with a first surface of said first flexible layer, electronic wires in connection with a first contact pad, both buried in said metal-oxide layer, a mesh suspended in said metal-oxide layer and a sealing layer covering at least said mesh.

59. The transducer structure according to claim 58, further comprising a residual substrate in connection with a second side of said metal-oxide layer.

60. The transducer structure according to claim 59, further comprising a second flexible layer in connection with said residual substrate at a second side of said metal-oxide layer.

61. The transducer structure according to claim 58, further comprising a second flexible layer in connection with a second side of said metal-oxide layer.

62. The transducer structure according to claim 58, further comprising a metal-oxide stack suspended in said oxide-metal layer.

63. The transducer structure according to claim 62, wherein metal layers in said metal-oxide stack are interconnected by metal vias in said metal-oxide layer and edges of said metal layers are exposed.

64. The transducer structure according to claim 62, wherein said metal-oxide stack comprises metal layers in a number selected from one to the total number of metal layers in said metal-oxide layer.

65. The transducer structure according to claim 58, further comprising a polysilicon layer extending parallel to and at a distance with said mesh.

66. The transducer structure according to claim 58, wherein said first contact pad is exposed from said first flexible layer.

67. The transducer structure according to claim 60, further comprising a second contact pad in connection with said wires and exposed from said second flexible layer.

68. The transducer structure according to claim 61, further comprising a second contact pad in connection with said wires and exposed from said second flexible layer.

69. The transducer structure according to claim 58, wherein said sealing layer further covers said first flexible layer.

70. The transducer structure according to claim 58, wherein said mesh is a metal mesh.

71. The transducer structure according to claim 58, wherein material of said first flexible layer is at least one selected from the group consisted of Polyimide, Parylene and Teflon.

72. The transducer structure according to claim 60, wherein material of said second flexible layer is at least one selected from the group consisted of Polyimide, Parylene and Teflon.

73. The transducer structure according to claim 61, wherein material of said second flexible layer is at least one selected from the group consisted of Polyimide, Parylene and Teflon.

74. The transducer structure according to claim 58, wherein said sealing layer is a PEDVD film.

75. The transducer structure according to claim 58, wherein said sealing layer is a polymer film.

76. The transducer structure according to claim 75, wherein material of said polymer of said sealing layer is at least one selected from the group consisted of Teflon and Parylene.

77. An array of flexible transducer units, wherein each transducer unit comprises: a first flexible layer, a metal-oxide layer in connection with a first surface of said first flexible layer, electronic wires in connection with a first contact pad, both buried in said metal-oxide layer, a mesh suspended in said metal-oxide layer and a sealing layer covering at least said mesh.

78. The transducer unit array according to claim 77, wherein each transducer unit further comprises a residual substrate in connection with a second side of said metal-oxide layer.

79. The transducer unit array according to claim 78, wherein each transducer unit further comprises a second flexible layer in connection with said residual substrate at a second side of said metal-oxide layer.

80. The transducer unit array according to claim 77, wherein each transducer unit further comprising a second flexible layer in connection with a second side of said metal-oxide layer.

81. The transducer unit array according to claim 77, wherein each transducer unit further comprises a metal-oxide stack suspended in said oxide-metal layer.

82. The transducer unit array according to claim 81, wherein metal layers in said metal-oxide stack are interconnected by metal vias in said metal-oxide layer and edges of said metal layers are exposed.

83. The transducer unit array according to claim 81, wherein said metal-oxide stack comprises metal layers in a number selected from one to the total number of metal layers in said metal-oxide layer.

84. The transducer unit array according to claim 77, wherein each transducer unit further comprises a polysilicon layer extending parallel to and at a distance with said mesh.

85. The transducer unit array according to claim 77, wherein said first contact pad is exposed from said first flexible layer.

86. The transducer unit array according to claim 79, wherein each transducer unit further comprises a second contact pad in connection with said wires and exposed from said second flexible layer.

87. The transducer unit array according to claim 80, wherein each transducer unit further comprises a second contact pad in connection with said wires and exposed from said second flexible layer.

88. The transducer unit array according to claim 77, wherein said sealing layer further covers said first flexible layer.

89. The transducer unit array according to claim 77, wherein said mesh is a metal mesh.

90. The transducer unit array according to claim 77, wherein material of said first flexible layer is at least one selected from the group consisted of Polyimide, Parylene and Teflon.

91. The transducer unit array according to claim 79, wherein material of said second flexible layer is at least one selected from the group consisted of Polyimide, Parylene and Teflon.

92. The transducer unit array according to claim 80, wherein material of said second flexible layer is at least one selected from the group consisted of Polyimide, Parylene and Teflon.

93. The transducer unit array according to claim 77, wherein said sealing layer is a PEDVD film.

94. The transducer unit array according to claim 77, wherein said sealing layer is a polymer film.

95. The transducer unit array according to claim 94, wherein material of said polymer of said sealing layer is at least one selected from the group consisted of Teflon and Parylene.

96. The transducer unit array according to claim 77, wherein each said transducer unit is separated by said first flexible layer.
